(19) United States
(12) Patent Application Publication
(10) Pub. No.: US 2006/0171244 A1
(43) Pub. Date: Aug. 3, 2006

(54) CHIP LAYOUT FOR MULTIPLE CPU CORE MICROPROCESSOR

(76) Inventor: Yoshiyuki Ando, Tokyo (JP)

Correspondence Address: RICHARD D. FUERLE, 1711 W. RIVER RD., GRAND ISLAND, NY, 14072, US

(21) Appl. No.: 10/906,108

(22) Filed: Feb. 3, 2005

(51) Int. Cl. G11C 8/00

(52) U.S. Cl. 365/233

(57) ABSTRACT

A microprocessor chip on a semiconducting substrate has at least two CPU cores that have hot spots on one side, a private cache memory for each CPU core that is located on the same side of said CPU core as the hot spot, a common cache memory that can be accessed by each CPU core, and an on-chip bus line connecting the CPU cores to the common cache memory. The CPU cores are located on each side of the on-chip bus line with their hot spots and their private cache memories positioned away from the on-chip bus line. Some of the CPU cores on the chip may be low power consumption CPU core and some of the CPU cores may be high speed CPU cores. The CPU cores may also be the same or different performance or purpose cores. A clock generator circuit may connect the CPU cores.

### BACKGROUND OF THE INVENTION

This invention relates to a central processing unit (CPU) microprocessor chip design in which there are at least two CPU cores on a chip. In particular, it relates to a multiple CPU core microprocessor where the CPU cores are positioned on the chip on both sides of an on-chip bus line, their hot spots are not centered on the cores and are on the side of the cores farthest from the bus line, and each CPU core has a private memory cache and access to an on-chip common (public) cache memory.

A conventional microprocessor structure has a single CPU core that executes all of the programs. As the processor operates at higher execution speeds to achieve higher performances it generates more heat, which cannot be easily removed. The excess heat limits the operation of the microprocessor, which is known as the “heat problem.” The heat problem also severely affects circuit reliability and increases cooling costs.

In order to solve this performance and heat problem, multiple CPU core microprocessors have been proposed. (See Clabes et al.,“Design and Implementation of the POWER5™ Microprocessor,” ISSCC 2004/SESSION 3/PROCESSORS/3.1, and Takayanagi et al. “A Dual-Core 64b UltraSPARC Microprocessor for Dense Server Applications,” ISSCC 2004/SESSION 3/PROCESSORS/3.2). The continuing advancement of microprocessor technology towards higher performance is making system level integration on a chip both possible and desirable. If multiple CPU cores are used on the same chip, operations can be switched from hotter cores to cooler cores or can be shared between cores to keep the temperatures down.

U.S. Pat. No. 6,804,632 discloses power consumption control technology for multiple core CPUs. The performance and power consumption of multiple core CPU integrated circuits is controlled by monitoring both the temperature in various areas of the chip and the activity of each CPU core. In U.S. Pat. No. 6,711,447, another power consumption control technology for multiple core CPU is disclosed, where the circuit performance and power consumption of the cores is controlled by modulating the CPU frequency and voltage.

### SUMMARY OF THE INVENTION

This invention creates a chip design for multiple core CPU microprocessors that controls the heat problem while maintaining the performance of the microprocessor by means of a heat generation circuit block location arrangement on a chip. Even if the operation of each CPU is switched or controlled by monitoring its operation temperature or execution speed, as in certain prior inventions, when the CPU cores are close together heat will remain in a very small area and the temperature may exceed the maximum permitted temperature. In this invention, local hot spots are separated as much as possible, but with a minimum reduction in processing speed.

An object of the present invention is to provide a high performance, heat-efficient multiple core CPU microprocessor chip layout. Multiple core CPU microprocessors made according to this invention have an efficient balance between heat reduction and higher performance.

### BRIEF DESCRIPTION OF THE DRAWINGS

FIG. 1 is a prior art chip layout showing the existing Power5™ Microprocessor.

FIG. 2 is a certain presently preferred embodiment of a chip layout according to this invention for a microprocessor having two CPU cores.

FIG. 3 is a certain presently preferred embodiment of a chip layout according to this invention for a microprocessor having three CPU cores of 2 different types.

FIG. 4 is a certain presently preferred embodiment of a chip layout according to this invention for a microprocessor having four CPU cores of two different types.

FIG. 5 is a certain presently preferred embodiment of a chip layout according to this invention for a microprocessor having a multiplicity of CPU cores of two different types.

FIG. 6 is another certain presently preferred embodiment of a chip layout according to this invention for a microprocessor having multiple CPU cores.

FIG. 7 is an alternative certain presently preferred embodiment of a chip layout according to this invention for a microprocessor having multiple CPU cores with a clock generator circuit.

### DESCRIPTION OF THE PREFERRED EMBODIMENTS

It will be understood from this description that the present invention can be implemented in conventional microprocessor technology, and that the described embodiments will operate accordingly if designed and fabricated in accordance with known standard processor design rules and methodologies. These rules and methodologies are well-known in the art and will not be repeated for this description.

In this invention, there are at least two CPU core microprocessors on an integrated circuit chip; preferably, there are at least four CPU core microprocessors on the chip. The cores have hot spots that are not centered on the cores; i.e., they are on one side of the cores. The cores are positioned on the semiconducting substrate of the chip on both sides of an on-chip bus line with their hot spots positioned away from the bus line. In that way, heat is dispersed more easily and the chip temperature does not exceed the maximum limit. Each CPU core has a private cache memory, on the same side of the core as the hot spot, so it is also positioned away from the bus line, which further helps to reduce the temperature of the chip as private cache memories are also usually a source of heat. There is a common cache memory on the chip that can be accessed by the CPU cores through the on-chip bus line and the CPU cores are located on one side of that common cache memory. The common cache memory density or size can vary (a typical common cache memory size is from 255 KB to a few MB).

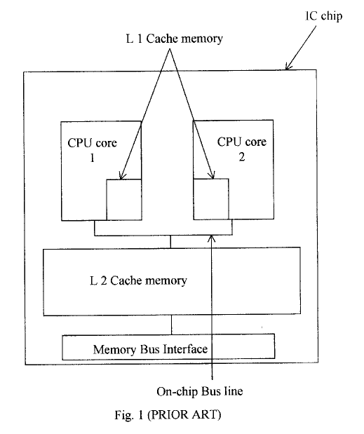

FIG. 1 shows an example of a prior art microprocessor chip having two CPU cores. It is based on a picture from Clabes et al.,“Design and Implementation of the POWER5™ Microprocessor,” ISSCC 2004/SESSION 3/PROCESSORS/3.1. The location of the hot spots is not given, but hot spots are typically located at or near the private cache memories, L1.

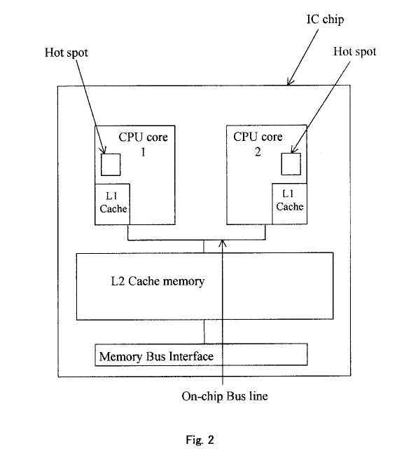

FIG. 2 shows an embodiment of the present invention. An integrated circuit chip on a semiconducting substrate has two CPU core microprocessors, a common memory cache, and an on-chip bus line that connects each core to the common memory cache. Each core has a private memory cache and a hot spot, where the private caches (L1) and the hot spots are symmetrical and on opposite sides of the on-chip bus line. The hot spots are not centrally located on the cores, but are closer to one edge of the cores. The cores are mirror images of each other and the hot spots are separated from each other as much as possible, which reduces the heat problem. The private memory caches (L1) are also not centrally located on the cores and are also positioned as far as possible from the on-chip bus line. The hot spots may be located on the private memory cores, the address generator unit (see “A 4-GHz 130-nm Address Generation Unit With 32-bit Sparse-Tree Adder Core,” IEEE Journal of Solid-State Circuits, vol., 38, No. 5, May 2003), or at other locations, depending upon the particular processor and how it is being used.

Comparing FIG. 1 to FIG. 2, the multiple CPU core processors in FIG. 2 have a disadvantage in view of the longer distance from the L1 cache to the on-chip bus line, which delays the signal. If the CPU core generates little heat this is true, but a CPU core that generates significant heat must reduce its operating speed to reduce its temperature. This means that the cooling advantage achieved in FIG. 2 enables the CPU cores to operate longer at higher speeds. If the CPU cores have large private caches, they execute programs internally without requiring frequent access to the common cache because of the large hit rate of its large density private cache.

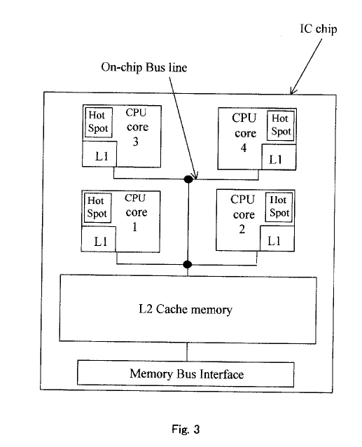

FIG. 3 illustrates an embodiment with four CPU core microprocessors on the chip. In this embodiment, there is an on-chip bus line which extends vertically from the common cache memory (L2) and is connected to each CPU core. If a high speed operation is requested, CPU cores 1 or 2 or both are used as they are closest to common memory cache L2 and cores 3 and 4 are used where high speed is not needed. In order to achieve a high transfer rate, the on-chip bus line typically has a bus width of more than 128 bits, which means there are more than 128 parallel wire lines, which makes wiring difficult. Signals flow between the CPU cores and the common cache memory in both directions on the bus line. For this reason, the vertical on-chip bus line of this invention has the advantages of efficiently using the area on the chip and shorter distances between the CPU cores and the common cache.

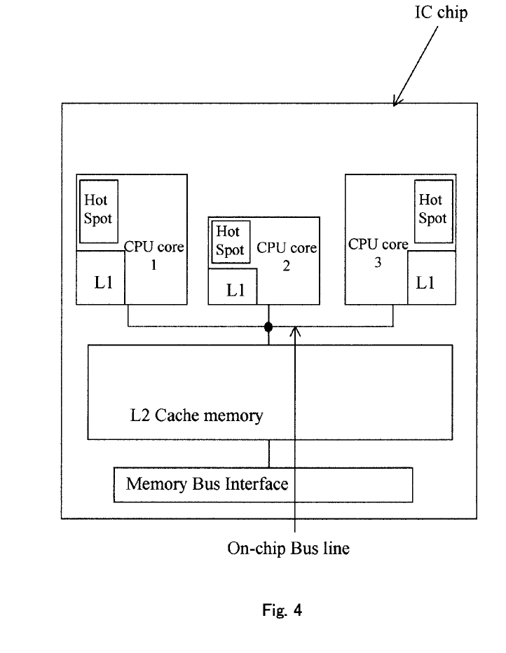

FIG. 4 shows another embodiment of this invention where there are three CPU core microprocessors on the chip. CPU core 1 and CPU core 3 are on opposite sides of the bus line and are mirror-symmetrical to each other. CPU cores 1 and 3 are for high speed operation and CPU core 2 is for low power operation. Since the hot spots on CPU cores 1 and 3 are located far from the bus line, when CPU cores 1 and 3 are operating at high speeds the heat problem is reduced.

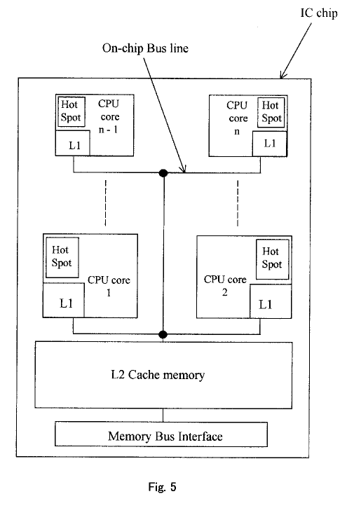

FIG. 5 shows another embodiment where the number of CPU cores is from 4 to n, where “n” may be 8 to 16 or more. An on-chip bus line connects common cache memory L2 to each CPU core.

In U.S. Pat. No. 6,789,167, a circuit block diagram for a multiple CPU core processor is disclosed where each CPU core has private cache memory and common cache memory which is connected to the memory bus interface. There are two-types of microprocessors. One is an SMP (Symmetric Multiple Processor) and another is an ASMP (Asymmetric Multiple Processor). In an SMP type processor, the CPU cores have the same performance and any of the CPU cores can be assigned to execute any program. For SMP type processors, the execution of programs can be moved from higher temperature CPU cores to lower temperature CPU cores. For high speed data transfer, the CPU cores are positioned close to the common cache. In an SMP type of processor, all the cores have the same structure. In U.S. Pat. No. 6,711,447, as disclosed above, the circuit performance and power consumption of the cores is controlled by modulating the CPU frequency and the voltage. A threshold voltage control using a body bias control and internal bus width control are also effective to control power consumption and performance.

FIGS. 4 and 5 show asymmetric multiple processors. In FIG. 4, cores 1 and 3 are the same and core 2 is a different performance or purpose core. In FIG. 5, cores 1 and 2 are the same cores, cores n-1 and n are different performance or purpose cores, and the remaining cores may be either the same or different performance or purpose cores.

In U.S. Patent Application No. 2004/0215987 CPU cores that have different power consumption performances or different execution speed performances are on the same chip and the program to be executed is divided among the CPU cores based on their performance characteristics.

The CPU cores in FIGS. 4 and 5 have different performance characteristic or different purposes, such as graphic applications. In FIG. 4, when a multiple CPU core processor is requested that has a high execution speed, if CPU core 1 has the highest speed, CPU core 1 is assigned to execute that program. On the other hand, when a processor is requested that has low power consumption, if CPU core 2 consumes the least power, CPU core 2 will execute the program. And when operation modes are requested, such as high speed, normal speed, and low power consumption mode, for high speed modes both CPU cores 1 and 3 will operate, for normal speed mode CPU core 1 or 3 will operate alternatively according to its temperature, and for low power consumption mode CPU core 2 will operate. A high speed CPU processor may be placed closer to the bus line, but in FIG. 4 the high speed cores 1 and 3 have been separated to reduce heat. High speed CPU cores may have a wider bus width, such as a 32 or 64 bit internal bus, or a higher operation speed, or lower threshold voltage transistors, while slower CPU cores may have a narrower bus width, such as a 16 or 32 bit bus, or a lower operation speed, or higher threshold voltage transistors. Both SMP and ASMP types of processors may have sleeping CPU cores in their operation modes.

There are two methods of lowering the power consumption of those sleeping mode CPU cores. One is to apply a lower supply voltage or a lower frequency clock supply, or to raise the threshold voltage of transistors in CPU core by controlling their body bias. The other method is to completely shut down CPU operations by stopping the supply voltages and clocks to some or all of the circuits of the sleeping CPU core. A complete shut down of sleeping CPU cores can effectively save consumption power, especially leakage current. When the temperature of one or more of the CPU cores rises to a predetermined level where it is overheated, this shut down method is required. Two predetermined temperatures may be needed in order to secure a smooth operation. At the first (lower) temperature level the program execution status and operating information of such CPU cores are transferred to other CPU cores or to the common cache so that the executing program can be continued or resumed. At the second (higher) temperature CPU core is shut down.

In the above-mentioned U.S. Pat. No. 6,804,632 and U.S. Patent Application No. 2004/0215987, an additional monitor circuit monitors each core's temperature in order to throttle the core, switch executions to another CPU core, or shut down the core. However, there are two ways to realize these CPU control methods without a monitor circuit. One is to have each core monitor its own temperature, exchange this data with other cores directly or through access with a common cache that stores all the CPU core data, and control its temperature by throttling or enhancing its operation. When its temperature exceeds a first temperature, it sends the signal to transfer executing programs to another lower temperature CPU core and then shuts down at a second higher temperature. Another method is for a throttled or sleep mode CPU core to monitor other CPU cores' temperatures and when a CPU core reaches the first temperature or the second temperature, the monitor CPU core switches the execution programs to a lower temperature CPU core or shuts down a CPU core that is at the second temperature level.

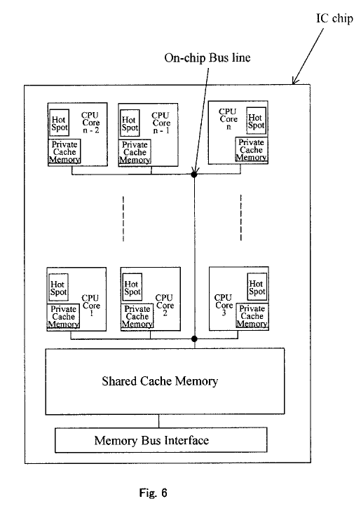

FIG. 6 shows different performance or different purpose multiple CPU core microprocessors in which there are “n” CPU cores that are connected to an on-chip bus line which extends vertically from common cache memory (L2). In this embodiment, the CPU cores that operate are selected according to various requests such as speed performance or power consumption. CPU cores 1 and 2 are high speed cores but CPU core 3 is the highest speed core. They are positioned closer to the common cache memory L2 to increase the speed. In FIG. 6, the bus line is off-center because the cores closest to the bus line are used for high speed operation and the cores on the left are used for low power consumption. When the same performance is required for each CPU core, the private cache size increase for the CPU cores located far from the common cache can be used. As mentioned previously, CPU cores that have a larger private cache size access the common cache less frequently than do CPU cores having a smaller private cache size. When the delay time of the on-chip bus line signal is large for a CPU core that is located far from the common cache, the latency (wait clock) may be used to design a high data transfer rate for the on-chip bus line. If the delay time of the on-chip bus signal is about 1 clock cycle for a CPU core that is located far from the common cache, this CPU core can receive the correct data from one clock cycle later, which means for this CPU core one clock latency or 1 clock wait is used. For a low speed CPU core this latency may have only a small influence on its performance due to its low program execution speed. By adjusting this latency period for a CPU core that is a long distance from the common cache, especially a low speed type, the location of the CPU cores can be more flexible. And the combination of this latency period and modifying the private cache size is effective for multiple CPU core microprocessors.

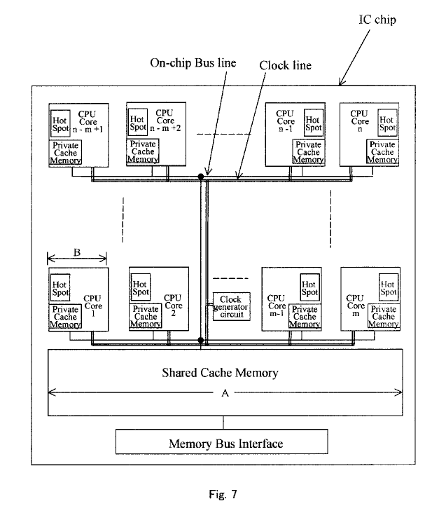

FIG. 7 shows the position of a clock generator circuit on a chip having multiple core microprocessors. The clock generator circuit connects all of the microprocessors and provides the clock signal necessary to synchronize their processing. In multiple core CPU processors, the locations of the clock generator and delivery circuits are important. When each CPU processor executes programs at about the same speed and uses the same clock speed, it is preferable to centrally locate the clock generator circuit in order to minimize the delay time from the clock generator circuit to the most distant CPU processor. When some CPU processors are higher speed, it is preferable to locate the clock generator circuit closer to those processors. In FIG. 7, the CPU core numbers in one row is decided by the formula: m×B≦A m: CPU core numbers in one row, B: one CPU core size, A: common cache size.

While the invention has been particularly shown and described with reference to a preferred embodiment or, not, it will be understood by those skilled in the art that various changes in form and detail may be made therein without departing from the spirit and scope of the invention.

What is claimed is:

1. A microprocessor chip on a semiconducting substrate comprising
(A) at least two CPU cores that have a hot spot on one side;
(B) a private cache memory for each CPU core, where said private cache memories are located on the same side of said CPU core as said hot spots;
(C) a common cache memory that can be accessed by each CPU core; and
(D) an on-chip bus line connecting said CPU cores to said common cache memory, where CPU cores are located on each side of said on-chip bus line with their hot spots and their private cache memories positioned away from said on-chip bus line.

2. A microprocessor chip according to claim 1 wherein there are two CPU cores on said chip.

3. A microprocessor chip according to claim 1 wherein at least one of said CPU cores on said chip is a low power consumption CPU core and at least one of said CPU core on said chip is a high speed CPU core.

4. A microprocessor chip according to claim 3 wherein said high speed CPU cores are located closer to said on-chip bus line than said low power consumption CPU cores.

5. A microprocessor chip according to claim 3 wherein said high speed CPU cores are located closer to said common cache memory than said low power consumption CPU cores.

6. A microprocessor chip according to claim 3 wherein the execution of programs can be assigned to either said high speed CPU cores or to said low power consumption CPU cores.

7. A microprocessor chip according to claim 1 wherein at least two of said CPU cores on said chip are the same.

8. A microprocessor chip according to claim 1 wherein at least one of said CPU cores on said chip is different from another CPU core on said chip in its operating power requirements and processing capabilities.

9. A microprocessor chip according to claim 1 wherein at least two of said CPU cores differ in their private cache size.

10. A microprocessor chip according to claim 1 wherein all of said CPU cores on said chip differ in their respective operating power requirements and processing capabilities.

11. A microprocessor chip according to claim 1 wherein there are three CPU cores on said chip.

12. A microprocessor chip according to claim 1 wherein there are four CPU cores on said chip.

13. A microprocessor chip according to claim 1 wherein a clock generator circuit connects said CPU cores.

14. A microprocessor chip according to claim 1 wherein said hot spots are located at said private cache memories.

15. A microprocessor chip according to claim 1 wherein CPU cores that are farther from said common cache memory have a larger private cache size.

16. A method of processing data using a microprocessor chip according to claim 1 comprising executing a program using at least one of said CPU cores.

17. A microprocessor chip on a semiconducting substrate comprising
(A) at least four CPU cores, where said CPU cores have a hot spot that is located on one side;
(B) a private cache memory for each CPU core that is located on the same side of said CPU core as said hot spot;
(C) a common cache memory that can be accessed by each CPU core; and
(D) an on-chip bus line that connects said CPU cores to said common cache memory, where CPU cores are located on each side of said on-chip bus line with their hot spots and their private cache memories positioned away from said on-chip bus line.

18. A microprocessor chip according to claim 16 wherein at least one of said CPU cores on said chip is different from another CPU core on said chip in its operating power requirements and processing capabilities.

19. A microprocessor chip on a semiconducting substrate comprising
(A) at least four CPU cores, where said CPU cores have a hot spot that is located on one side, and at least one of said CPU cores on said chip is a low power consumption core and at least one of said CPU cores on said chip is a high speed core;
(B) a clock generator circuit connecting said CPU cores;
(C) a private cache memory for each CPU core that is located on the same side of said CPU core as said hot spot;
(C) a common cache memory that can be accessed by each CPU core; and
(E) an on-chip bus line connecting said CPU cores to said common cache memory, where CPU cores are located on each side of said on chip bus line with their hot spots and their private cache memories positioned away from said on-chip bus line and said at least one high speed CPU core is located closer to said on-chip bus line than said at least one low power consumption CPU core.

20. A microprocessor chip according to claim 18 wherein there are four CPU core, two on each side of said on-chip bus line.
